(19) United States
(12) Patent Application Publication
(10) Pub. No.: US 2012/0013325 A1
(43) Pub. Date: Jan. 19, 2012

(54) METHOD FOR DETERMINING A NEEDLING CLOSING IN A PIEZOINJECTOR

(76) Inventors: Erik Tonner, Gerlingen (DE); Kai Barnickel, Stuttgart (DE)

(21) Appl. No.: 13/147,757

(22) PCT Filed: Jan. 5, 2010
(86) PCT No.: PCT/EP2010/050030

§ 371 Date: Sep. 27, 2011

(30) Foreign Application Priority Data
Feb. 10, 2009 (DE) 10 2009 000 741.5

(51) Int. Cl. G01R 29/22

(52) U.S. Cl. 324/109

(57) ABSTRACT

In a method for determining a needle closing of a valve needle that is driven by a piezoactuator, a signal of a voltage present at the piezoactuator is measured and the needle closing is detected from a curve of the signal.

### FIELD OF THE INVENTION

The present invention relates to a method for determining a needle closing, to a system for determining a needle closing, to a computer program, and to a computer program product.

### BACKGROUND INFORMATION

A piezoinjector, having a piezoactuator and a valve element, is designed to realize a fuel injection in an engine. During an injection process, various subfunctions of the valve element, e.g. opening and closing, are realized. These subfunctions can be acquired using sensors.

Thus, a method is known for determining an end time of a fuel injection carried out by a fuel injector that has a valve element driven by a piezoactuator and a piezosensor that is mechanically coupled to the piezoactuator. In a step of the method, a sensor signal of the piezosensor is acquired. From this sensor signal, an acoustic signal caused by a closing of the valve element is determined, and from the acoustic signal the time of closing of the valve element is determined. Up to now, or in previous investigations, the time of closing of the nozzle needle has been acquired using the piezosensor, which however results in additional costs because for this purpose two electrical lines must be run from the fuel injector to the control device, and two control device pins are required per fuel injector.

### SUMMARY

Example embodiments of the present invention provide a method for determining a needle closing of a valve needle of an injection valve whose actuating element is fashioned as a piezoactuator, the valve needle being driven by the piezoactuator. Here, a signal of a voltage adjacent to the piezoactuator is measured, and the needle closing is detected on the basis of a curve of the signal.

In a realization of the method, it is examined whether the curve of the signal has a characteristic feature, typically a maximum, a sharp bend, or a spike that indicates the closing of the needle. In this manner, a detection of the needle closing based on the measured voltage of the piezoactuator is possible.

Via the curve of the voltage, structure-borne sound caused during the closing of the valve needle, or a corresponding acoustic signal, is detected. Using the method described herein, the recognition of the structure-borne sound produced by the closing of the valve needle or of a nozzle needle is possible via an evaluation of the signal of the voltage at the piezoactuator. Thus, in an example embodiment of the method a physical effect that influences the voltage signal is detected.

In an example embodiment, it is provided that the valve needle is situated in a nozzle, the movement of the valve needle being controlled by the piezoactuator via at least one valve element. In this case, the valve needle is indirectly controlled by the piezoactuator. However, a direct actuation of the valve needle by the piezoactuator is also possible. In a possible sequence, the piezoactuator extends in an injection valve fashioned as a so-called servo valve; in this manner, pressure differences are caused at an upper and lower side of the valve needle, and these differences additionally cause a back-and-forth movement of the valve needle.

During operation, the piezoactuator is triggered by a current. This current charges the piezoactuator, and in addition the valve is opened by the movement of a valve needle. The valve needle is closed again by the discharging of the piezoactuator. When the method is carried out, the curve of the voltage signal is examined in a region after driving of the piezoactuator by the current has taken place, after the voltage has decreased to a value close to 0 volts. Standardly, the curve of the signal is caused by the flowing current. However, the feature that is to be detected in the method and that indicates the needle closing is not excited by the described current. This feature in the curve of the voltage signal of the piezoactuator is caused by the structure-borne sound of the valve needle when the needle closes.

The signal can be processed during an evaluation of the curve of the signal. In this evaluation, a bandpass filtering can be applied using cutoff frequencies, so that in this manner particular frequencies of the signal are filtered for example by a low-pass or high-pass filtering. Moreover, the signal, or a curve of the signal, can be squared and additionally summed during the evaluation. Alternatively or in addition, it is possible to use a calculation rule for evaluation. This calculation rule determines the slopes for multiple pairs of straight lines, or secants, each passing through two measurement points of the curve, and forms the difference in the determined slopes for each pair of straight lines.

In the evaluation using this calculation rule, for a multiplicity of pairs of measurement points of a curve or a curve of the signal, a straight line or secant is applied per measurement point. The measurement points must not follow one another immediately in time. In an example embodiment, it is possible for a first straight line of a pair to run through an mth measurement point and an m−kth measurement point, while a second straight line of this pair runs through an nth measurement point and an n+kth measurement point, where n>m; for example, n=m+1. The straight lines thus extend along k measurement points, where k is at least two. A value for k can be chosen arbitrarily, as a function of the required measurement precision. It can be sufficient for k to be a one-digit number, e.g. 5. From the slopes of the two straight lines through the mth measurement point and the nth measurement point, a difference is calculated from the slopes of the two straight lines. A plurality of successive differences for slopes of each pair of straight lines can be formed; e.g. for a first pair for the mth and nth measurement point, for a second pair, of an m+1th measurement point and of an n+1th measurement point, etc.; a pth pair of straight lines will be applied in the m+p−1th and n+p−1th measurement point. In this case, it is possible to form p values for differences of slopes of each pair of straight lines. Of these p values, a maximum value is determined that, as a maximum, indicates the characteristic feature.

In the evaluation, the signal, or its curve, can be processed using a plurality of the above-named mathematical steps that can be successively applied to the signal.

In an example embodiment, first the bandpass filtering is carried out for prespecified frequencies, and this already frequency-filtered signal is squared; subsequently, a summation of the squared signal takes place, and finally the above-described calculation rule is applied to the summed signal. This sequence can also vary; moreover, not all the named processing steps need be carried out.

Using the method, inter alia a time of the needle closing can be determined.

Example embodiments of the present invention provide a system for determining a needle closing of a valve needle that is driven by a piezoactuator. This system is designed to measure a signal of a voltage applied to the piezoactuator and to detect the needle closing from a curve of the signal.

In an example embodiment, the valve needle is situated in a nozzle and is controlled by the piezoactuator via at least one valve element. Standardly, the at least one valve element works together with the valve needle and/or with the nozzle. During the needle closing, in which the valve needle moves into a closing position relative to the nozzle, the valve needle and/or the nozzle produces structure-borne sound, or an acoustic signal, that is transmitted to the piezoactuator via the at least one valve element. Alternatively, it is also possible for the valve needle to be driven directly by the piezoactuator. Here, it is for example provided that the injection valve is actuated by the piezoactuator. This causes pressure differences to arise between a nozzle needle seat and the upper part of the valve needle. These pressure differences cause the opening of the valve needle.

The described system is provided for carrying out all the steps of the presented method. Some individual steps of this method may also be carried out by individual components of the system. In addition, functions of the system or functions of individual components of the system may be realized as steps of the method. Moreover, it is possible for steps of the method to be realized as functions of individual components of the system or of the overall system.

In addition, example embodiments of the present invention provide a computer program having program code for carrying out all steps of a described method when the computer program is executed on a computer or on a corresponding computing unit, in particular in a system as described herein.

The computer program product having program code stored on a computer-readable data carrier is fashioned for the execution of all steps of a described method when the computer program is executed on a computer or on a corresponding computing unit, in particular in a system as described herein.

Standardly, the needle closing of a piezoinjector fashioned for acting on a valve element of an internal combustion engine produces a structure-borne sound that can be temporally acquired using a sensor integrated in a piezoactuator of the piezoinjector and a suitable signal processing. However, the sensor integrated into the piezoactuator results in additional costs in the manufacture of the actuator and thus in the manufacture of the injector, as well as in the control device.

These costs are partly those of the sensor integration and partly those of the electrical contacting of the sensor. The measures described herein make it possible to avoid these costs.

Example embodiments of the present invention enable the detection of the time of the needle closing from the voltage adjacent to the piezoactuator; in this manner, the sensor effect conventionally used is detected directly at the piezoactuator. Example embodiments of the present invention are suitable for example for injectors for accumulator injections, so-called common-rail injectors, which have piezoactuators and valve elements.

Further advantages and aspects of example embodiments of the present invention are described below and are shown the accompanying Figures.

It is to be understood that the above-named features and the features to be explained below can be used not only in the indicated combination, but also in other combinations or by themselves without departing from the scope hereof.

### BRIEF DESCRIPTION OF THE DRAWINGS

FIG. 1 shows two examples of diagrams having operating parameters for comparing different operating conditions of a valve element.

FIG. 2 shows two further examples of diagrams; a first diagram shows a curve of a signal for a voltage at an actuator, and the second diagram shows a curve of a signal for a sensor.

FIG. 3 shows examples of a plurality of diagrams for comparing operating parameters that are acquired using a sensor in the realization of a conventional procedure, with operating parameters provided in the context of the method according to an example embodiment of the present invention.

FIG. 4 shows a schematic representation of a system according to an example embodiment of the present invention fashioned for the realization of the method according to an example embodiment of the present invention.

### DETAILED DESCRIPTION

Example embodiments of the present invention are schematically shown in the drawings, and is described in detail below with reference to the drawings.

The Figures are described as an interrelated whole; identical reference characters designate identical components.

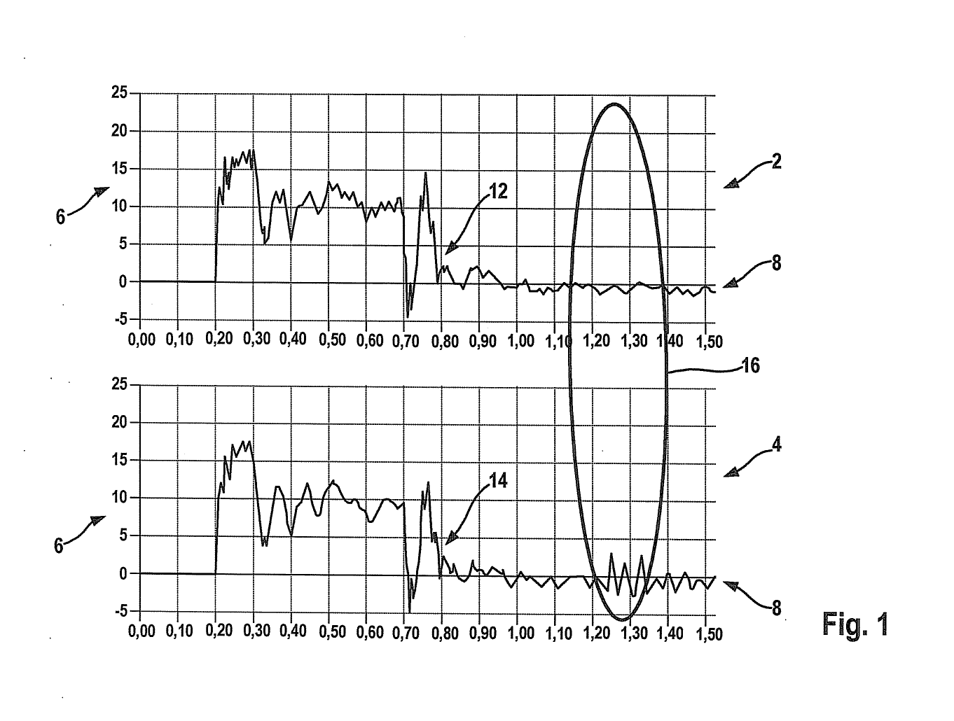

In each of diagrams 2, 4 shown in FIG. 1, a vertically oriented axis 6 for a voltage is plotted over a time axis 8.

First diagram 2 shows a first curve 12 of a voltage measured by a sensor module that is allocated to a piezoactuator. It is provided that this piezoactuator is fashioned for actuating a nozzle having a valve needle via a valve element of an internal combustion engine. The piezoactuator acts on the valve needle indirectly via the valve element, and the needle is thereby moved back and forth and is thus opened and closed. First curve 12 of the voltage was acquired while the nozzle needle was inactive, whereas second curve 14 in second diagram 4 was acquired by the sensor module while the valve needle was active. Comparison of the regions of the two curves 12, 14 inside ellipse 16 shows that curve 14, with active valve needle, has a spike within this region, whereas curve 12, with inactive valve needle, has no remarkable characteristics within this marked region.

In a conventional procedure for detecting the needle closing, the additional sensor module is integrated into the piezoactuator. As soon as the valve needle reaches its seat, a structure-borne sound signal is produced that is measurable by the sensor module.

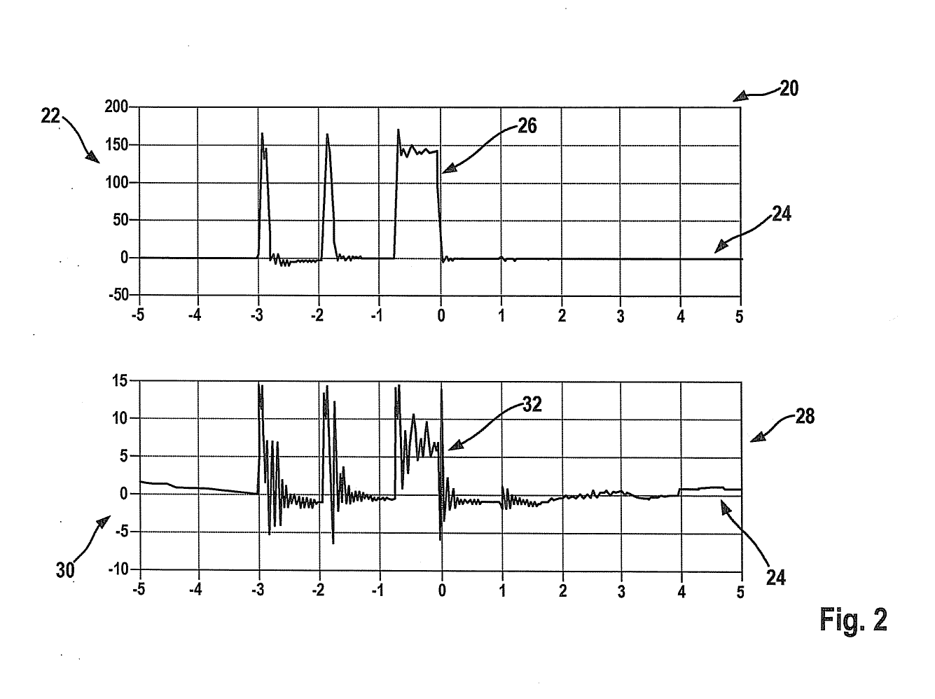

First diagram 20 in FIG. 2 has a vertically oriented axis 22 for a voltage that is plotted over a time axis 24. First diagram 20 in FIG. 2 shows a curve 26 of a voltage of a piezoactuator that is acquired during operation of a piezoactuator fashioned to act on a nozzle having a valve needle via a valve element. The structure-borne sound signal is recognized along voltage curve 26 via a characteristic feature.

In second diagram 28 in FIG. 2, shown below the first diagram, the curve of the associated sensor signal is plotted along a vertically oriented axis 30 over time axis 24. A spike in the range of a millisecond, caused by the closing of the needle of the valve element, is recognizable along voltage curve 26 only with difficulty. In contrast, processed or evaluated curve 32 of originally measured voltage signal curve 26 does illustrate the closing of the valve needle through a noticeable spike or sharp bend in curve 32 in the range of a millisecond.

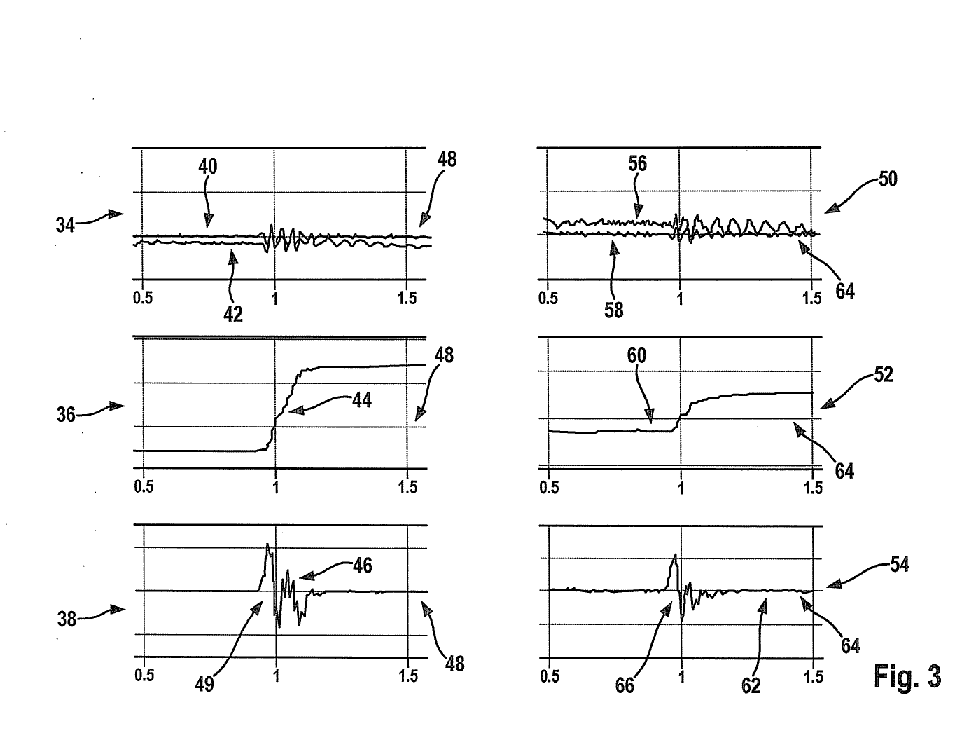

The three diagrams 34, 36, 38 situated one over the other at left in FIG. 3 each show temporal zooms or enlarged segments of curves 40, 42, 44, 46 of sensor signals, or processed sensor signals, as conventionally provided by a sensor that works together with a piezoactuator. First diagram 34 in

FIG. 3 shows, along a time axis 48, curve 40 of a raw value of a voltage as a sensor signal and curve 42 after a filtering, for example a bandpass filtering, of curve 40. Second diagram 36 shows, along time axis 48, curve 44 after squaring and summation has been carried out of bandpass-filtered signal 42. In third diagram 38 in FIG. 3, along time axis 48 curve 46 is shown of curve 44, squared and summed through the application of a calculation rule. This calculation rule includes a determination of differences in slopes of respective pairs of straight lines, or secants, each straight line running through two measurement points of curve 44. The differences of the slopes determined for multiple pairs of straight lines are compared, and from a maximum difference a maximum 49 is determined.

Maximum 49 of curve 46 appears at the same time as the sharp bend in curve 44. In this manner, the time of the needle closing is determined. Maximum 49 of curve 46, in the range of a millisecond, is caused by the closing of the valve needle detected by the sensor.

Diagrams 50, 52, 54, shown at right in FIG. 3, show examples of temporal zooms or enlarged segments of curves 56, 58, 60, 62 for signals or processed signals as acquired in the method according to an example embodiment of the present invention.

In this example embodiment of the method, it is provided that a piezoactuator is fashioned for operating a valve needle situated in a nozzle via a valve element for an internal combustion engine. During operation of the internal combustion engine, current is supplied to the piezoactuator. This current supply causes the piezoactuator to act on the valve element, causing the valve needle of the nozzle to move back and forth, which opens and closes the nozzle.

During execution of the example embodiment of the method, a voltage present at the piezoactuator is measured. Curve 56 of a signal of this voltage is plotted in fourth diagram 50 in FIG. 3 along a time axis 64. In the same diagram 50, under this the filtered (for example bandpass-filtered with regard to frequency) curve 58 of curve 56 of the signal is shown. In the fifth diagram in FIG. 3, a curve 60 of the now-revised signal is shown, resulting from squaring and summing of curve 58 from fourth diagram 50.

Sixth diagram 54 shows a curve 62 of values of differences formed from slopes of respective pairs of straight lines or secants, a first straight line running through a first pair of measurement points and a second straight line running through a second pair of measurement points of curve 60 in fifth diagram 52. A maximum 66 is determined for the determined differences of multiple pairs of straight lines.

This curve 62 has as a resulting characteristic feature, in the range of a millisecond, a maximum 66 formed as a spike. A comparison of curve 66 in the sixth diagram with curve 46 in the third diagram shows that this sharp bend 66 happens at the same point in time as does maximum 49 in sensor signal curve 46.

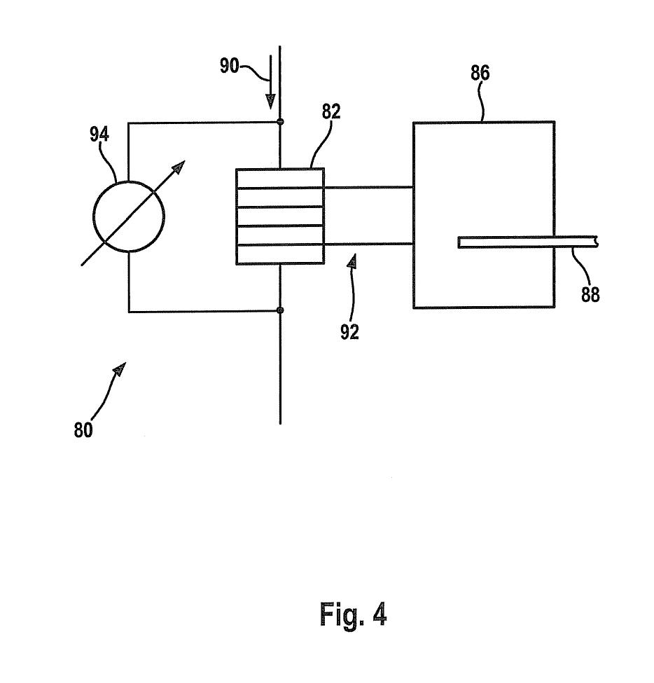

FIG. 4 shows a schematic representation of a system 80 that is fashioned for the realization of an example embodiment of the method. System 80 has a piezoactuator 82 that is fashioned inside an internal combustion engine, for controlling.

Between piezoactuator 82 and nozzle 86 with valve needle 88, or a nozzle needle, in the present example embodiment there is situated a valve element 92. An interaction between piezoactuator 84 and nozzle 86 with valve needle 88 takes place indirectly via valve element 92. It is provided that during operation by piezoactuator 82 a current 90 is conducted to a prespecified profile. Through this current 90, a dimension of piezoactuator 82 is modified. The driving of valve element 92 by moving piezoactuator 82 also moves valve needle 88 of nozzle 86, and this needle is inter alia opened. In the described example embodiment, it is provided that piezoactuator 84 drives the valve needle. This results in pressure differences between a seat of valve needle 88 and the upper part of valve needle 88. These pressure differences result in the opening of valve needle 88.

When valve needle 88 closes after having been opened, structure-borne sound is produced that acts on piezoactuator 82 and causes a voltage at piezoactuator 82 that is measured by a voltmeter 94 when the method is realized. A signal of the voltage measured by voltmeter 94 can have a sharp bend 66 caused by the structure-borne sound, as shown in diagrams 50, 52, 54, along a curve 56, 58, 60, 62 of the signal, or of a processed signal.

1-13. (canceled)

14. A method for determining a needle closing of a valve needle driven by a piezoactuator, comprising:
measuring a signal of a voltage present at the piezoactuator; and
detecting the needle closing from a curve of the signal, the signal being squared and summed.

15. The method according to claim 14, further comprising determining whether the curve of the signal has a characteristic feature that indicates the needle closing.

16. The method according to claim 14, wherein the piezoactuator is triggered during operation, the curve of the signal being examined, during execution of the method, in a region after driving the piezoactuator has been triggered, after a voltage has decreased to a value of 0 volts.

17. The method according to claim 14, wherein a structure-borne sound caused by the closing valve needle is detected via the curve of the signal.

18. The method according to claim 14, wherein the valve needle (88) is situated in a nozzle and is driven by the piezoactuator via at least one valve element.

19. The method according to claim 14, wherein the signal is processed.

20. The method according to claim 14, wherein a bandpass filtering with cutoff frequencies is applied to the signal, and particular frequencies of the signal are filtered.

21. The method according to claim 14, wherein a time at which the needle closes is determined.

22. A device, comprising:
a system adapted to determine a needle closing of a valve needle driven by a piezoactuator, the system adapted to measure a signal of a voltage present at the piezoactuator and to detect the needle closing from a curve of the signal, the system adapted to square and sum the signal.

23. A non-transitory computer-readable storage medium with an executable program stored thereon, wherein the program instructs a microprocessor to perform a method as recited in claim 13.
